(19) United States
(12) Patent Application Publication
(10) Pub. No.: US 2025/0324740 A1
(43) Pub. Date: Oct. 16, 2025

(54) SEMICONDUCTOR DEVICE AND METHOD FOR MANUFACTURING THE SAME

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Yuki SHIBUTANI, Hakusan (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/813,330

(22) Filed: Aug. 23, 2024

(30) Foreign Application Priority Data
Apr. 15, 2024 (JP) 2024-065669

(51) Int. Cl. H01L 29/78; H01L 29/16; H01L 29/20; H01L 29/40; H01L 29/66

(52) U.S. Cl. CPC H10D 84/146; H10D 30/0297; H10D 30/668; H10D 64/117; H10D 62/8325; H10D 62/8503

(57) ABSTRACT

According to one embodiment, a semiconductor device includes a first electrode, a first semiconductor region, a second semiconductor region, a conductive portion, a gate electrode, and a second electrode. The first semiconductor region including a first portion. The second semiconductor region is provided on the first portion. The gate electrode faces the first portion via a gate insulating layer. The second electrode includes platinum, cobalt, or nickel. The second electrode includes a first electrode portion and a second electrode portion. The first electrode portion is arranged with the first portion and the second semiconductor region in the second direction. The first portion is positioned between the first electrode portion and the gate electrode. The second electrode portion is provided on the gate electrode via an insulating layer. The second semiconductor region is positioned between the first electrode portion and the second electrode portion.

### CROSS-REFERENCE TO RELATED APPLICATIONS

This application is based upon and claims the benefit of priority from Japanese Patent Application No. 2024-065669, filed on Apr. 15, 2024; the entire contents of which are incorporated herein by reference.

### FIELD

Embodiments of the present invention generally relate to a semiconductor device and a method for manufacturing the same.

### BACKGROUND

Semiconductor devices such as metal-oxide-semiconductor field effect transistors (MOSFETs) are used for applications such as power conversion. It is desirable for the on-resistance of the semiconductor device to be low.

### BRIEF DESCRIPTION OF THE DRAWINGS

FIG. 1 is a perspective cross-sectional view illustrating a semiconductor device according to the first embodiment;

FIG. 2 is a partially enlarged cross-sectional view of FIG. 1;

FIGS. 3A and 3B are cross-sectional views illustrating a method for manufacturing the semiconductor device according to the first embodiment;

FIGS. 4A and 4B are cross-sectional views illustrating the method for manufacturing the semiconductor device according to the first embodiment;

FIGS. 5A and 5B are cross-sectional views illustrating the method for manufacturing the semiconductor device according to the first embodiment;

FIG. 6 is a cross-sectional view illustrating a semiconductor device according to the reference example; and

FIG. 7 is a perspective cross-sectional view illustrating a semiconductor device according to the second embodiment.

### DETAILED DESCRIPTION

According to one embodiment, a semiconductor device includes a first electrode, a first semiconductor region of a first conductivity type, a second semiconductor region of the first conductivity type, a conductive portion, a gate electrode, and a second electrode. The first semiconductor region is provided on the first electrode. The first semiconductor region including a first portion. The second semiconductor region is provided on the first portion. An impurity concentration of the first conductivity type in the second semiconductor region is greater than an impurity concentration of the first conductivity type in the first semiconductor region. The conductive portion is provided in the first semiconductor region via a first insulating portion. The gate electrode is provided on the conductive portion via a second insulating portion. The gate electrode faces the first portion via a gate insulating layer in a second direction. The second direction is perpendicular to a first direction from the first electrode toward the first semiconductor region. The second electrode is electrically connected to the conductive portion. The second electrode includes one or more selected from the group consisting of platinum, cobalt, and nickel. The second electrode includes a first electrode portion and a second electrode portion. The first electrode portion is arranged with the first portion and the second semiconductor region in the second direction. The first portion is positioned between the first electrode portion and the gate electrode. The second electrode portion is provided on the gate electrode via an insulating layer. The second semiconductor region is positioned between the first electrode portion and the second electrode portion.

Various embodiments will be described hereinafter with reference to the accompanying drawings. The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions. In the specification and drawings, components similar to those described or illustrated in a drawing thereinabove are marked with like reference numerals, and a detailed description is omitted as appropriate.

In the following descriptions and drawings, notations of n⁺ and n represent relative levels of impurity concentrations in the conductivity type. That is, the notation “n⁺” shows a relatively higher impurity concentration than an impurity concentration for the notation “n”. The embodiments described below may be implemented by reversing the conductivity type of each semiconductor region to p-type.

### First Embodiment

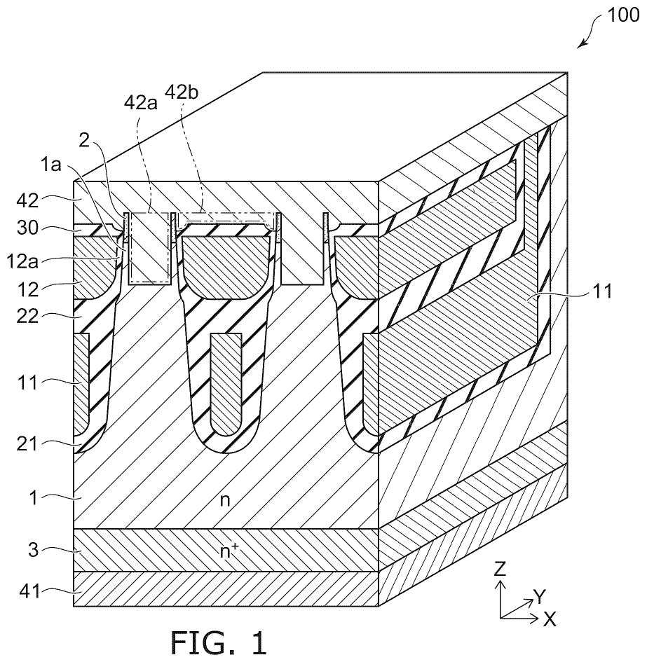

FIG. 1 is a perspective cross-sectional view illustrating a semiconductor device according to the first embodiment.

As shown in FIG. 1, the semiconductor device 100 according to the first embodiment includes an n-type (a first conductivity type) drift region 1 (a first semiconductor region), an n⁺-type source region 2 (a second semiconductor region), an n⁺-type drain region 3, a conductive portion 11, a gate electrode 12, a gate insulating layer 12a, a first insulating portion 21, a second insulating portion 22, an insulating layer 30, a drain electrode 41 (a first electrode), and a source electrode 42 (a second electrode). The semiconductor device 100 is a MOSFET.

An XYZ orthogonal coordinate system is used in the description of the embodiments. The direction from the drain electrode 41 toward the n-type drift region 1 is taken as a Z-direction (a first direction). Two mutually-orthogonal directions perpendicular to the Z-direction are taken as an X-direction (a second direction) and a Y-direction. In the description, the direction from the drain electrode 41 toward the n-type drift region 1 is called “up/above/higher than”, and the opposite direction is called “down/below/lower than”. These directions are based on the relative positional relationship between the drain electrode 41 and the n-type drift region 1 and are independent of the direction of gravity.

The drain electrode 41 is provided in the lower part of the semiconductor device 100. The n⁺-type drain region 3 is provided on the drain electrode 41 and is electrically connected to the drain electrode 41. The n-type drift region 1 is provided on the n⁺-type drain region 3. The n-type impurity concentration in the n-type drift region 1 is lower than the n-type impurity concentration in the n⁺-type drain region 3. The n-type drift region 1 includes a first portion 1a. The n⁺-type source region 2 is provided on the first portion 1a. The n-type impurity concentration in the n⁺-type source region 2 is higher than the n-type impurity concentration in the n-type drift region 1.

The conductive portion 11 is provided in the n-type drift region 1 via the first insulating portion 21. The gate electrode 12 is provided on the conductive portion 11 via the second insulating portion 22. The gate electrode 12 faces the first portion 1a via the gate insulating layer 12a in the X-direction. The gate electrode 12 may also face a part of the n⁺-type source region 2 via the gate insulating layer 12a. The insulating layer 30 is provided on the gate electrode 12.

The source electrode 42 is provided on the n-type drift region 1, the n⁺-type source region 2, and the insulating layer 30. The source electrode 42 includes a first electrode portion 42a and a second electrode portion 42b. The first electrode portion 42a is arranged with the first portion 1a and the n⁺-type source region 2 in the X-direction. The second electrode portion 42b is located on the insulating layer 30. The first portion 1a is positioned between the first electrode portion 42a and the gate electrode 12 in the X-direction. The n⁺-type source region 2 is positioned between the first electrode portion 42a and the second electrode portion 42b in the X-direction.

The source electrode 42 is in contact with the n-type drift region 1 and the n⁺-type source region 2, and is electrically connected to the n-type drift region 1 and the n⁺-type source region 2. The gate electrode 12 and the source electrode 42 are electrically isolated from each other by the insulating layer 30.

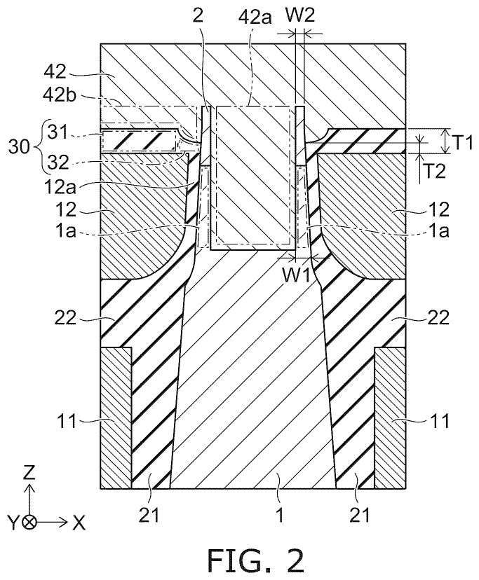

FIG. 2 is a partially enlarged cross-sectional view of FIG. 1. As shown in FIG. 2, the insulating layer 30 may include a first insulating part 31 and a second insulating part 32. The second insulating part 32 is positioned between the first insulating part 31 and the n⁺-type source region 2 in the X-direction. The thickness T2 in the Z-direction of the second insulating part 32 is less than the thickness T1 in the Z-direction of the first insulating part 31. Therefore, the upper surface of the second insulating part 32 is positioned lower than the upper surface of the first insulating part 31.

The width of the first portion 1a and the width of the n⁺-type source region 2 may gradually narrow toward the Z-direction. For example, the width W2 of the n⁺-type source region 2 is narrower than the width W1 of the first portion 1a. The “width” is the length in the X-direction.

As shown in FIG. 1, each of the first portion 1a, the n⁺-type source region 2, the conductive portion 11, the gate electrode 12, the first electrode portion 42a, and the second electrode portion 42b is provided in a plurality in the X-direction. For example, a pair of first portions 1a separated from each other in the X-direction are positioned between a pair of gate electrodes 12 separated from each other in the X-direction. A pair of n⁺-type source regions 2 separated from each other in the X-direction are positioned between a pair of second electrode portions 42b separated from each other in the X-direction. The first electrode portion 42a is positioned between the pair of first portions 1a and between the pair of n⁺-type source regions 2.

Each first portion 1a, each n⁺-type source region 2, each conductive portion 11, each gate electrode 12, each first electrode portion 42a, and each second electrode portion 42b extend in the Y-direction and are arranged in a stripe shape. The end portion of the conductive portion 11 in the Y-direction is provided upward and is in contact with the source electrode 42. The conductive portion 11 is electrically connected to the source electrode 42.

An example of the material of each component will now be described.

The n-type drift region 1, the n⁺-type source region 2, and the n⁺-type drain region 3 include single-crystal silicon as a semiconductor material. The n-type drift region 1, the n⁺-type source region 2, and the n⁺-type drain region 3 include arsenic, phosphorus, or antimony as an n-type impurity. The conductive portion 11 and the gate electrode 12 include a conductive material such as polysilicon. The gate insulating layer 12a, the first insulating portion 21, the second insulating portion 22, and the insulating layer 30 include an insulating material such as silicon oxide, silicon nitride, or silicon oxynitride. The drain electrode 41 includes a metal such as aluminum. The source electrode 42 includes one or more selected from the group consisting of platinum, nickel, and cobalt. For example, a Schottky junction is formed between the n-type drift region 1 and the first electrode portion 42a.

The operation of the semiconductor device 100 will now be described.

The depletion layer spreads from the interface between the n-type drift region 1 and the source electrode 42 toward the n-type drift region 1. Due to the spread of this depletion layer, the first portion 1a is depleted. At this time, no current flows between the drain electrode 41 and the source electrode 42, and the semiconductor device 100 is in an off-state. When a voltage exceeding the threshold value is applied to the gate electrode 12, a channel (an inversion layer) is formed in the vicinity of the gate insulating layer 12a in the first portion 1a. Electrons flow from the n⁺-type source region 2 to the n⁺-type drain region 3 through the channel. As a result, the semiconductor device 100 is turned on.

When the semiconductor device 100 switches to the off-state, the positive voltage applied to the drain electrode 41 with respect to the source electrode 42 increases. The electric potential of the conductive portion 11 is substantially the same as the electric potential of the source electrode 42. The n-type drift region 1 is electrically connected to the drain electrode 41. Due to the potential difference between the n-type drift region 1 and the conductive portion 11, the depletion layer spreads from the interface between the first insulating portion 21 and the n-type drift region 1 toward the n-type drift region 1. As the depletion layer spreads, the breakdown voltage of the semiconductor device 100 can be increased. Alternatively, while maintaining the breakdown voltage of the semiconductor device 100, the n-type impurity concentration in the n-type drift region 1 can be increased, and the on-resistance of the semiconductor device 100 can be reduced.

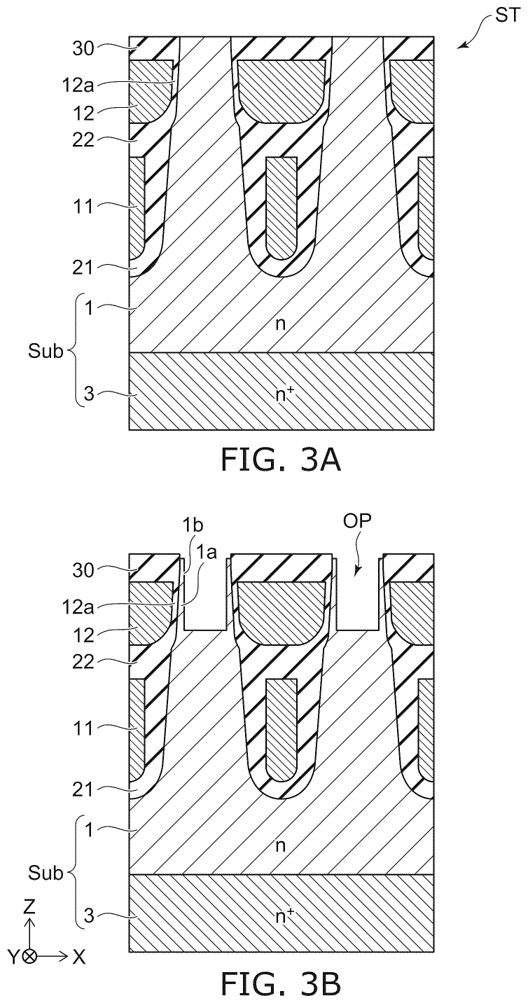

FIGS. 3A, 3B, 4A, 4B, 5A, and 5B are cross-sectional views illustrating a method for manufacturing the semiconductor device according to the first embodiment.

First, a semiconductor substrate Sub including the n-type drift region 1 and the n⁺-type drain region 3 is prepared. Multiple openings are formed on the upper surface of the n-type drift region 1 using a known method. As shown in FIG. 3A, the conductive portion 11, the gate electrode 12, the gate insulating layer 12a, the first insulating portion 21, the second insulating portion 22, and the insulating layer 30 are formed inside the opening. As a result, a structure body ST including the n-type drift region 1, the n⁺-type drain region 3, the conductive portion 11, the gate electrode 12, the first insulating portion 21, the second insulating portion 22, the insulating layer 30, and the gate insulating layer 12a is prepared.

The part of the n-type drift region 1 that is separated from the gate insulating layer 12a in the X-direction is removed by reactive ion etching (RIE). As a result, openings OP are formed on the upper surface of the n-type drift region 1, as shown in FIG. 3B. In the upper part of the n-type drift region 1, the first portion 1a and the second portion 1b located on the first portion 1a remain. At this time, the upper surface of the insulating layer 30 is positioned higher than the upper surface of the n-type drift region 1 (the upper surface of the second portion 1b).

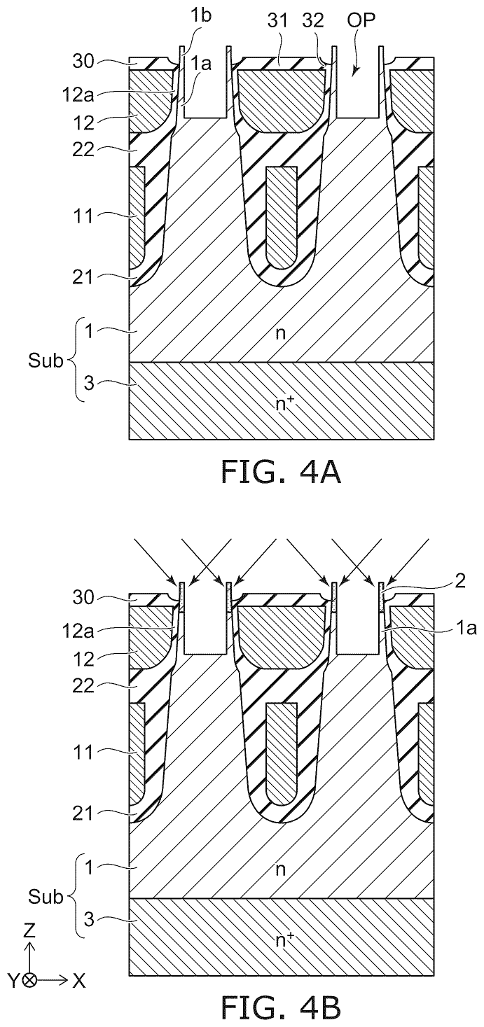

As shown in FIG. 4A, the upper surface of the insulating layer 30 is caused to be retreated by wet etching. At this time, etching also proceeds from the lateral direction at the end portion in the X-direction of the insulating layer 30. As a result, the thickness of the end portion in the X-direction of the insulating layer 30 becomes smaller than the thickness of the central portion. Thereby, the first insulating part 31 and the second insulating part 32 are formed in the insulating layer 30.

N-type impurities are ion-implanted into the second portion 1b. The n-type impurities are implanted from a direction inclined with respect to the Z-direction. Thereby, more n-type impurities are implanted into the second portion 1b than in the first portion 1a. The n-type impurities are activated by heat treatment; and the n⁺-type source region 2 is formed on the first portion 1a, as shown in FIG. 4B.

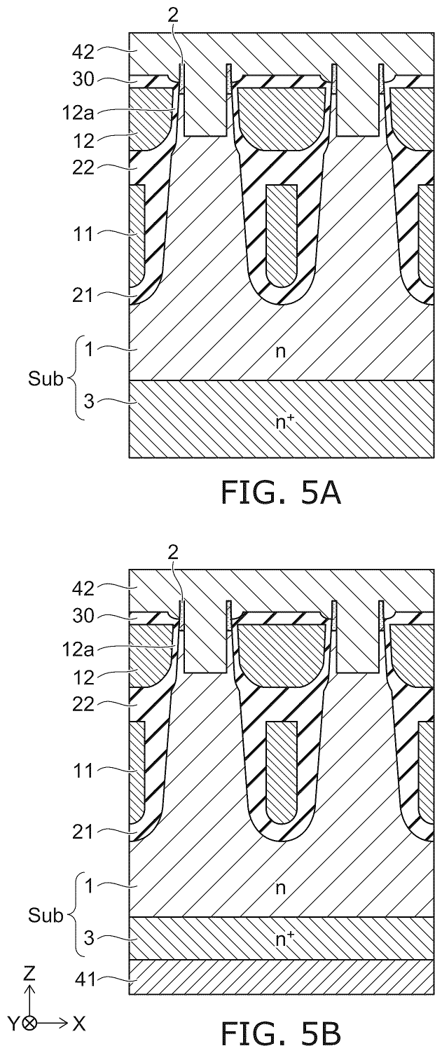

As shown in FIG. 5A, the source electrode 42 is formed on the n-type drift region 1, the n⁺-type source region 2, and the insulating layer 30 by sputtering. The lower surface of the n⁺-type drain region 3 is ground until the n⁺-type drain region 3 reaches a predetermined thickness. As shown in FIG. 5B, the drain electrode 41 is formed on the ground back surface of the n⁺-type drain region 3 by sputtering. By the above steps, the semiconductor device 100 according to the first embodiment is manufactured.

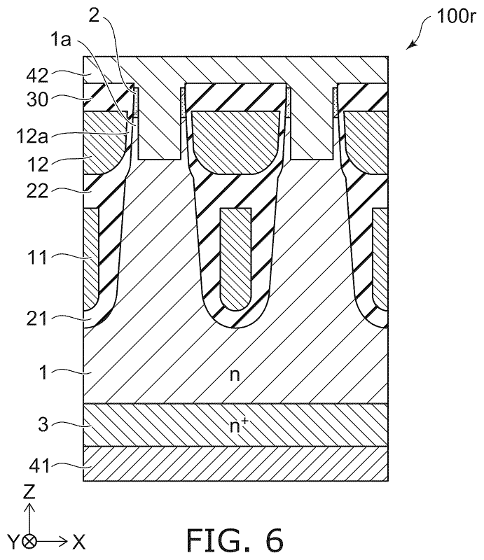

FIG. 6 is a cross-sectional view illustrating a semiconductor device according to the reference example.

In the semiconductor device 100r shown in FIG. 6, the upper surface of the insulating layer 30 is positioned higher than the n⁺-type source region 2. The source electrode 42 does not include the second electrode portion 42b. One side of the n⁺-type source region 2 is in contact with the first electrode portion 42a, and the other side of the n⁺-type source region 2 is in contact with the insulating layer 30.

Advantages of the first embodiment will now be described with reference to FIG. 6. In the semiconductor device 100 or 100r, it is desirable for the electrical resistance in the on-state (on-resistance) to be low. The on-resistance depends on the n-type impurity concentration in the n-type drift region 1, the channel density, the electrical resistance (contact resistance) between the n⁺-type source region 2 and the source electrode 42, etc. The “channel density” refers to the number of channels formed per unit area in the X-Y plane.

To increase the channel density, it is desirable for the cell pitch to be small. The cell pitch is, for example, represented as the distance between the center in the X-direction of one gate electrode 12 and the center in the X-direction of another gate electrode 12 adjacent thereto. In addition, in order to reduce the contact resistance between the n⁺-type source region 2 and the source electrode 42, it is desirable for the contact area between the n⁺-type source region 2 and the source electrode 42 to be large. In order to increase the contact area between the n⁺-type source region 2 and the source electrode 42 in the semiconductor device 100r, it is necessary to increase the size of the n⁺-type source region 2. However, as the size of the n⁺-type source region 2 increases, the cell pitch also increases and the channel density may decrease. Therefore, with regard to the semiconductor device 100r, reducing the contact resistance while maintaining the cell pitch is not easy.

In the semiconductor device 100 according to the first embodiment, the n⁺-type source region 2 is positioned between the first electrode portion 42a and the second electrode portion 42b. The n⁺-type source region 2 is in contact with both the first electrode portion 42a and the second electrode portion 42b. Therefore, in the semiconductor device 100, the contact area between the n⁺-type source region 2 and the source electrode 42 can be increased compared to the semiconductor device 100r. For example, the contact resistance can be further reduced while suppressing the increase in cell pitch. Alternatively, the cell pitch can be reduced while suppressing the increase in contact resistance. In either case, it is possible to reduce the on-resistance of the semiconductor device 100.

In addition, when the n⁺-type source region 2 is formed in the manufacture of the semiconductor device 100, n-type impurities are ion-implanted on both sides of the second portion 1b, as shown in FIG. 4B. On the other hand, when forming the n⁺-type source region 2 in the manufacture of the semiconductor device 100r, the n-type impurities are ion-implanted only on one side of the second portion 1b. Therefore, according to the structure of the semiconductor device 100, the n-type impurities implanted into the n⁺-type source region 2 can be increased, and the n-type impurity concentration in the n⁺-type source region 2 can be further increased. As a result, the on-resistance of the semiconductor device 100 can be further reduced.

As shown in FIG. 2, the insulating layer 30 preferably includes the first insulating part 31 and the second insulating part 32. The thickness T2 of the second insulating part 32 is less than the thickness T1 of the first insulating part 31. Since the thickness T2 is small and the upper surface of the second insulating part 32 is positioned lower than the upper surface of the first insulating part 31, the contact area between the n⁺-type source region 2 and the second electrode portion 42b can be further increased.

The width W2 of the n⁺-type source region 2 is preferably narrower than the width W1 of the first portion 1a. The narrower the width W2, the larger the number of n-type impurities included per unit volume of the n⁺-type source region 2. Therefore, the n-type impurity concentration in the n⁺-type source region 2 can be further increased. As a result, the on-resistance of the semiconductor device 100 can be further reduced.

### Second Embodiment

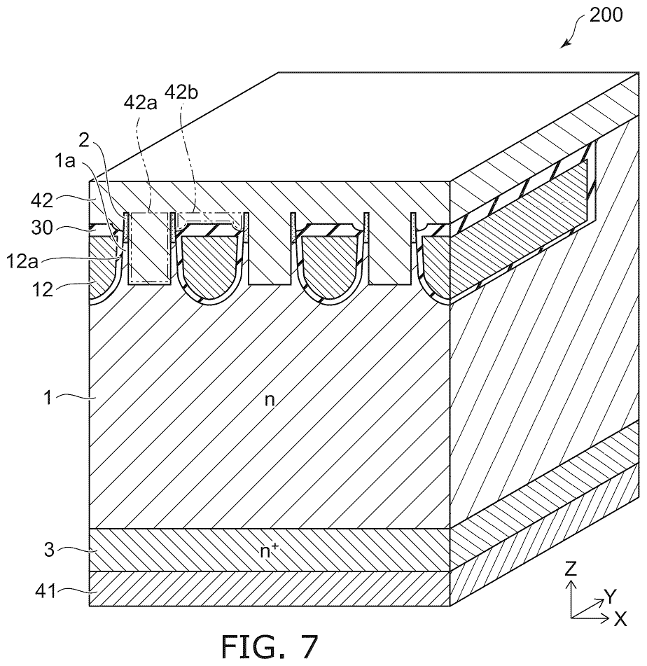

FIG. 7 is a perspective cross-sectional view illustrating a semiconductor device according to the second embodiment.

As shown in FIG. 7, the semiconductor device 200 according to the second embodiment includes the n-type drift region 1, the n⁺-type source region 2, the n⁺-type drain region 3, the gate electrode 12, the gate insulating layer 12a, the insulating layer 30, the drain electrode 41, and the source electrode 42. The semiconductor device 200 differs from the semiconductor device 100 in that it does not include the conductive portion 11.

The gate electrode 12 is provided in the n-type drift region 1 via the gate insulating layer 12a. The gate electrode 12 faces the first portion 1a via the gate insulating layer 12a in the X-direction.

The n-type drift region 1, the n⁺-type source region 2, and the n⁺-type drain region 3 include silicon carbide or gallium nitride as a semiconductor material. The source electrode 42 includes one or more selected from the group consisting of platinum and nickel. For example, a Schottky junction is formed between the n-type drift region 1 and the first electrode portion 42a. The operation of the semiconductor device 200 is substantially the same as that of the semiconductor device 100.

When each semiconductor region includes a compound semiconductor such as silicon carbide or gallium nitride, the breakdown voltage of the semiconductor device 200 can be increased and the on-resistance can be reduced compared to the case where each semiconductor region includes single-crystal silicon. Therefore, even when the conductive portion 11 is omitted, sufficient breakdown voltage or on-resistance can be obtained.

In the first embodiment, in order to increase the breakdown voltage or reduce the on-resistance of the semiconductor device 100, it is desirable for the semiconductor device 100 to include the conductive portion 11. However, if the conductive portion 11 can be omitted from the viewpoint of breakdown voltage or on-resistance, the conductive portion 11 may be omitted.

Embodiments of the present invention include the following features.

### (Feature 1)

A semiconductor device, comprising:
a first electrode;
a first semiconductor region of a first conductivity type provided on the first electrode, the first semiconductor region including a first portion;
a second semiconductor region of the first conductivity type provided on the first portion, an impurity concentration of the first conductivity type in the second semiconductor region being greater than an impurity concentration of the first conductivity type in the first semiconductor region;
a conductive portion provided in the first semiconductor region via a first insulating portion;
a gate electrode provided on the conductive portion via a second insulating portion, the gate electrode facing the first portion via a gate insulating layer in a second direction, the second direction being perpendicular to a first direction from the first electrode toward the first semiconductor region;
a second electrode electrically connected to the conductive portion, the second electrode including one or more selected from the group consisting of platinum, cobalt, and nickel, the second electrode including
   a first electrode portion arranged with the first portion and the second semiconductor region in the second direction, the first portion being positioned between the first electrode portion and the gate electrode, and
   a second electrode portion provided on the gate electrode via an insulating layer, the second semiconductor region being positioned between the first electrode portion and the second electrode portion.

### (Feature 2)

The semiconductor device according to claim 1, wherein
the insulating layer includes
   a first insulating part, and
   a second insulating part positioned between the first insulating part and the second semiconductor region in the second direction, and
   a thickness in the first direction of the second insulating part is less than a thickness in the first direction of the first insulating part.

### (Feature 3)

The semiconductor device according to feature 1 or 2, wherein
a length of an upper part of the second semiconductor region in the second direction is shorter than a length of a lower part of the second semiconductor region in the second direction.

### (Feature 4)

The semiconductor device according to any one of features 1 to 3, wherein
a pair of the first portions separated from in the second direction is provided,
a pair of the second semiconductor regions is provided on the pair of the first portions respectively, and
the first electrode portion is positioned between the pair of the first portions and between the pair of the second semiconductor regions.

### (Feature 5)

A semiconductor device, comprising:
a first electrode;
a first semiconductor region of a first conductivity type provided on the first electrode, the first semiconductor region including a first portion;
a second semiconductor region of the first conductivity type provided on the first portion, an impurity concentration of the first conductivity type in the second semiconductor region being greater than an impurity concentration of the first conductivity type in the first semiconductor region;
a gate electrode facing the first portion via a gate insulating layer in a second direction, the second direction being perpendicular to a first direction from the first electrode toward the first semiconductor region;
a second electrode including
   a first electrode portion arranged with the first portion and the second semiconductor region in the second direction, the first portion is positioned between the first electrode portion and the gate electrode, and
   a second electrode portion provided on the gate electrode via an insulating layer, the second semiconductor region being located between the first electrode portion and the second electrode portion.

### (Feature 6)

The semiconductor device according to feature 5, wherein
a Schottky junction is formed between the first semiconductor region and the first electrode portion.

### (Feature 7)

The semiconductor device according to feature 5 or 6, wherein
the first semiconductor region and the second semiconductor region include silicon carbide or gallium nitride, and
the second electrode includes one or more selected from the group consisting of platinum and nickel.

### (Feature 8)

A method for manufacturing a semiconductor device, comprising:
preparing a structure body including
   a first semiconductor region including a first portion and a second portion provided on the first portion, the first semiconductor region being of a first conductivity type,
   a conductive portion provided in the first semiconductor region via a first insulating portion,
   a gate electrode provided on the conductive portion via a second insulating portion, the gate electrode facing the first portion via a gate insulating layer in a second direction, the second direction being perpendicular to a first direction from the conductive portion toward the gate electrode, and
   an insulating layer provided on the gate electrode, the insulating layer being arranged with the second portion in the second direction;
removing a part of the first semiconductor region separated from the gate insulating layer in the second direction so that the first portion and the second portion are remained;
causing an upper surface of the insulating layer to be retreated to expose a side surface of the second portion; and
forming an electrode on the first semiconductor region and the insulating layer, the electrode including one or more selected from the group consisting of platinum, cobalt, and nickel.

### (Feature 9)

The method for manufacturing the semiconductor device according to feature 8, further comprising ion-implanting an impurity of the first conductivity type into the second portion to form a second semiconductor region of the first conductivity type,
an impurity concentration of the first conductivity type in the second semiconductor region being greater than an impurity concentration of the first conductivity type in the first semiconductor region,
the ion-implanting being performed after exposing the side surface of the second portion and before forming the electrode.

### (Feature 10)

The method for manufacturing the semiconductor device according to feature 9, wherein,
after causing the upper surface of the insulating layer to be retreated, the insulating layer includes a first insulating part and a second insulating part positioned between the first insulating part and the second semiconductor region in the first direction, and
a thickness in the first direction of the second insulating part is less than a thickness in the first direction of the first insulating part.

It is possible to confirm the relative levels of the impurity concentrations of the semiconductor regions in the embodiments described above, for example, using a scanning capacitance microscope (SCM). The carrier concentrations of the semiconductor regions may be considered to be equal to the activated impurity concentrations of the semiconductor regions. Accordingly, the relative levels of the carrier concentrations of the semiconductor regions can be confirmed using SCM. It is possible to measure the impurity concentrations of the semiconductor regions, for example, using a secondary ion mass spectrometer (SIMS).

For each embodiment described above, each embodiment may be implemented by reversing the n-type of the semiconductor region to the p-type.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device, comprising:
a first electrode;
a first semiconductor region of a first conductivity type provided on the first electrode, the first semiconductor region including a first portion;
a second semiconductor region of the first conductivity type provided on the first portion, an impurity concentration of the first conductivity type in the second semiconductor region being greater than an impurity concentration of the first conductivity type in the first semiconductor region;
a conductive portion provided in the first semiconductor region via a first insulating portion;
a gate electrode provided on the conductive portion via a second insulating portion, the gate electrode facing the first portion via a gate insulating layer in a second direction, the second direction being perpendicular to a first direction from the first electrode toward the first semiconductor region;
a second electrode electrically connected to the conductive portion, the second electrode including one or more selected from the group consisting of platinum, cobalt, and nickel, the second electrode including
a first electrode portion arranged with the first portion and the second semiconductor region in the second direction, the first portion being positioned between the first electrode portion and the gate electrode, and
a second electrode portion provided on the gate electrode via an insulating layer, the second semiconductor region being positioned between the first electrode portion and the second electrode portion.

2. The semiconductor device according to claim 1, wherein
the insulating layer includes
a first insulating part, and
a second insulating part positioned between the first insulating part and the second semiconductor region in the second direction, and
a thickness in the first direction of the second insulating part is less than a thickness in the first direction of the first insulating part.

3. The semiconductor device according to claim 1, wherein
a length of an upper part of the second semiconductor region in the second direction is shorter than a length of a lower part of the second semiconductor region in the second direction.

4. The semiconductor device according to claim 1, wherein
a pair of the first portions separated from in the second direction is provided,
a pair of the second semiconductor regions is provided on the pair of the first portions respectively, and
the first electrode portion is positioned between the pair of the first portions and between the pair of the second semiconductor regions.

5. A semiconductor device, comprising:
a first electrode;
a first semiconductor region of a first conductivity type provided on the first electrode, the first semiconductor region including a first portion;
a second semiconductor region of the first conductivity type provided on the first portion, an impurity concentration of the first conductivity type in the second semiconductor region being greater than an impurity concentration of the first conductivity type in the first semiconductor region;
a gate electrode facing the first portion via a gate insulating layer in a second direction, the second direction being perpendicular to a first direction from the first electrode toward the first semiconductor region;
a second electrode including
a first electrode portion arranged with the first portion and the second semiconductor region in the second direction, the first portion is positioned between the first electrode portion and the gate electrode, and
a second electrode portion provided on the gate electrode via an insulating layer, the second semiconductor region being located between the first electrode portion and the second electrode portion.

6. The semiconductor device according to claim 5, wherein
a Schottky junction is formed between the first semiconductor region and the first electrode portion.

7. The semiconductor device according to claim 5, wherein
the first semiconductor region and the second semiconductor region include silicon carbide or gallium nitride, and
the second electrode includes one or more selected from the group consisting of platinum and nickel.

8. A method for manufacturing a semiconductor device, comprising:
preparing a structure body including
a first semiconductor region including a first portion and a second portion provided on the first portion, the first semiconductor region being of a first conductivity type,
a conductive portion provided in the first semiconductor region via a first insulating portion,
a gate electrode provided on the conductive portion via a second insulating portion, the gate electrode facing the first portion via a gate insulating layer in a second direction, the second direction being perpendicular to a first direction from the conductive portion toward the gate electrode, and
an insulating layer provided on the gate electrode, the insulating layer being arranged with the second portion in the second direction;
removing a part of the first semiconductor region separated from the gate insulating layer in the second direction so that the first portion and the second portion are remained;
causing an upper surface of the insulating layer to be retreated to expose a side surface of the second portion; and
forming an electrode on the first semiconductor region and the insulating layer, the electrode including one or more selected from the group consisting of platinum, cobalt, and nickel.

9. The method for manufacturing the semiconductor device according to claim 8, further comprising ion-implanting an impurity of the first conductivity type into the second portion to form a second semiconductor region of the first conductivity type,
an impurity concentration of the first conductivity type in the second semiconductor region being greater than an impurity concentration of the first conductivity type in the first semiconductor region,
the ion-implanting being performed after exposing the side surface of the second portion and before forming the electrode.

10. The method for manufacturing the semiconductor device according to claim 9, wherein,
after causing the upper surface of the insulating layer to be retreated, the insulating layer includes a first insulating part and a second insulating part positioned between the first insulating part and the second semiconductor region in the first direction, and
a thickness in the first direction of the second insulating part is less than a thickness in the first direction of the first insulating part.
